(19) United States
(12) Patent Application Publication
(10) Pub. No.: US 2015/0364667 A1
(43) Pub. Date: Dec. 17, 2015

(54) COMBINED CERAMIC MATRIX COMPOSITE AND THERMOELECTRIC STRUCTURE FOR ELECTRIC POWER GENERATION

(71) Applicant: UNITED TECHNOLOGIES CORPORATION, Hartford, CT (US)

(72) Inventor: David C. Jarmon, Kensington, CT (US)

(21) Appl. No.: 14/759,678

(22) PCT Filed: Jan. 18, 2013
(86) PCT No.: PCT/US13/22144

§ 371 Date: Jul. 8, 2015

(51) Int. Cl. H01L 35/32; H01L 35/34; H01L 35/06

(52) U.S. Cl. CPC H01L 35/32; H01L 35/06; H01L 35/34

(57) ABSTRACT

An electrical power generation system consists of a ceramic hot face liner of a gas path enclosure thermally and mechanically connected to thermoelectric elements mounted on a conformal thermally conducting layer on the liner. Cooling channels connected to the backside of the thermoelectric elements provide a thermal gradient across the elements and resulting electrical power output. Clamps to maintain thermal and physical contact of all elements in the system are provided to maximize power generation.

### BACKGROUND

The present invention relates to passive conversion of waste heat in a hot gas flow path into electrical energy.

Waste heat in thermal power generation systems can be converted into electrical energy using thermoelectric devices placed across temperature gradients in selected regions of the structures provided the thermal profiles are manageable and the regions physically accessible. Thermoelectric devices are solid state electronic devices that have a near infinite shelf life, are maintenance free, and contain little or no hazardous materials. In some situations such as gas turbine powered air and sea craft, thermoelectric power generation can be considered an added source of energy. In other situations such as hypersonic vehicle (e.g., scram jet) applications, thermoelectric power generation using the thermal gradients adjacent to a hot gas path may be critical to mission success.

Hypersonic vehicle transportation offers potential for future commercial and military application decreasing time to target thereby extending global reach. These vehicles are anticipated to be powered by scram jet (supersonic combustion ram jet) engines during the hypersonic portion of flight. The structure which forms the hypersonic gas flow path in a scram jet engine is referred to as a heat exchanger (HEX) in the art. Hypersonic flow paths are fuel cooled since air cooling is not practical in a hypersonic environment. Fuel cooling also serves to preheat the fuel which adds energy to the fuel for combustion. Scram jet engines have no rotating mechanical elements which, in a conventional jet engine, are used to generate accessory power required for fuel pumps and onboard electrical systems. Hypersonic vehicles are currently envisioned to require either auxiliary power units (APUs) and/or batteries to meet vehicle power requirements. Both solutions add onboard weight, volume and system complexity. In addition, they require periodic maintenance and commonly contain hazardous materials, such as acids or hydrazine.

Other propulsion and APU requirements associated with hot gas streams and other sources of extraordinary thermal gradients can benefit from passive thermoelectric power generation. Examples include next generation turbine related propulsion and power generation systems where efficiency scales directly as the absolute temperature differential between input and exhaust working fluids.

### SUMMARY

An electrical power generation system is configured to surround a hot gas path of an energy source to provide passive thermoelectric energy. The system includes a ceramic hot face liner coated with a thermally conducting material capable of being shaped to form mounting surfaces that conform to inner surfaces of thermoelectric elements attached to the liner to maximize thermal communication between the elements and the hot face liner. Cooling channels attached to outer surfaces of the thermoelectric elements result in a thermal gradient across the elements and resulting thermoelectric power generation. Clamps that apply clamping forces to maintain physical and thermal contact between all elements and the ceramic liner result in improved power generation.

A method to form an electric power generation system consists of first fabricating a ceramic hot gas path liner. A layer of thermally conducting material is then deposited on the liner. Flat surfaces are formed on the layer that allow good thermal and physical contact between the thermally conducting layer and flat inner surfaces of thermoelectric elements mounted on the layer. Metal cooling ducts mounted on flat outer surfaces of the thermoelectric elements provide good thermal and physical contact between the thermoelectric elements and the cooling ducts. A compressive clamping force is then applied to the cooling ducts, thermoelectric elements, and hot gas path liner to maximize the thermal gradient across the thermoelectric elements and resulting thermoelectric power generation of the system.

### BRIEF DESCRIPTION OF THE DRAWINGS

FIG. 1 is a schematic cross-section of an electrical power generation system according to the present invention.

FIG. 2 is an expanded cross-sectional view of a portion of the system in FIG. 1.

FIG. 3 is a perspective view of a complete power generation module according to the present invention.

FIG. 4 is a diagram of a method for forming an electrical power generation system according to the present invention.

FIGS. 5A-5I illustrate an embodiment of the method of forming an electrical power generation system according to the present invention.

### DETAILED DESCRIPTION

The present invention is a passive thermoelectric energy generation system associated with extremely hot gas path generation and control such as that found in scram jet or other hypersonic vehicle propulsion systems. It should be understood that other propulsion and energy generation systems such as rocket based, turbine based or fusion based systems may benefit therefrom.

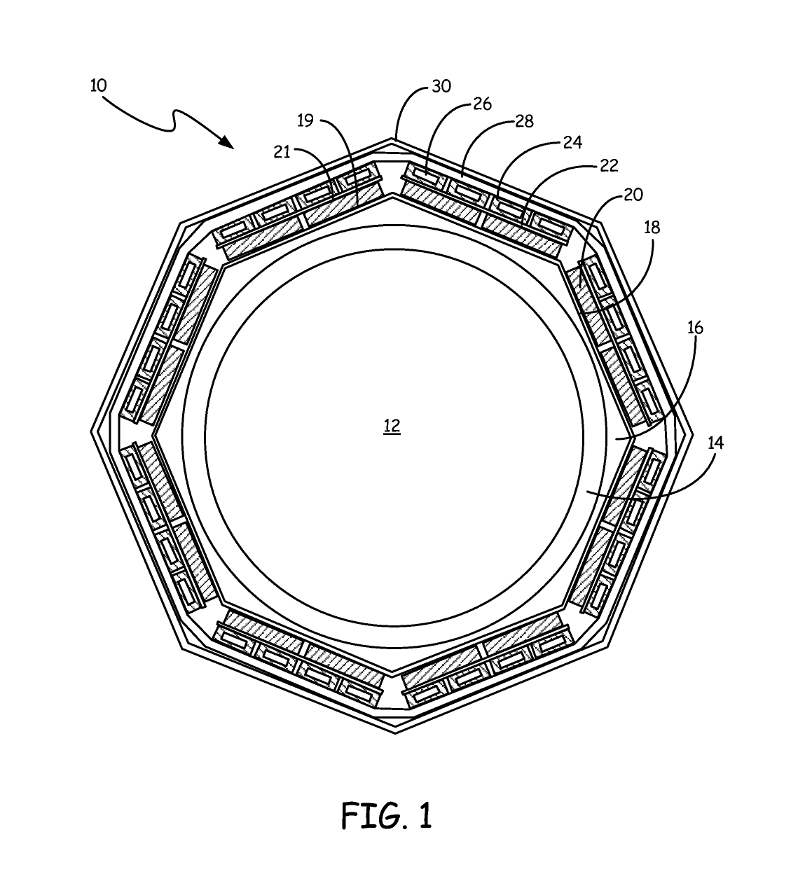

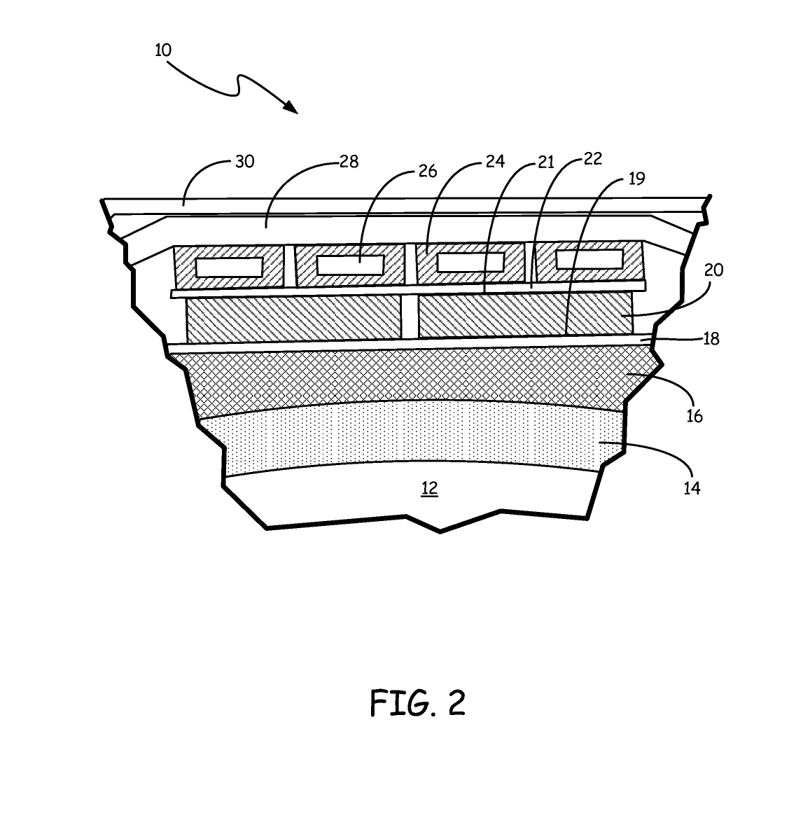

A schematic cross-section of an embodiment of the invention is shown in FIG. 1. Thermoelectric power generation structure 10 is a cylindrical enclosure surrounding hot gas path 12 of a propulsion or other power generating system. Temperatures in the gas path can exceed 1100° C. A larger cross-section of a portion of structure 10 is shown in FIG. 2 for clarity.

The structure comprises hot face liner 14 capable of withstanding the thermal, chemical and mechanical degradation afforded by a high velocity thermal gas stream impinging on hot face liner 14 during operation. Hot face liner 14 is encased in thermally conductive, shaped layer 16. Shaped layer 16 is a necessary and central feature of the invention and will be described in detail. Optional layer 18 on thermally conductive shaped layer 16 may act as a reaction barrier. Thermoelectric (TE) element 20 may be mounted directly on thermally conductive shaped layer 16 or on optional layer 18 such that inner surface 19 of TE element 20 is in direct thermal and physical contact with thermally conductive layer 16 or optional layer 18. As discussed later, TE element 20 is the source of the power of thermoelectric power generation structure 10.

Optional compliant layer 22 may be mounted on thermoelectric element 20 such that outer surface 21 of TE element 20 is in direct thermal and physical contact with compliant layer 22. Metal cooling ducts 24 may be mounted on compliant layer 22 or directly on outer surface 21 of TE element 20 and may carry coolant fluid 26 to extract heat from outer surface 21 of TE element 20. Metal cooling ducts 24, TE elements 20 and intervening optional compliant layers 22 and reaction barrier layer 18 are compressibly forced (i.e. clamped) against each other and to conductive shaped interface 16 by canted coil spring 28. Metal shell 30 encloses the aforementioned components and provides a structure for canted coil spring 28 to react against and to form thermoelectric power generation structure 10. In addition, metal shell 30 can provide a controlled atmosphere within thermoelectric power generation structure 10.

Individual components of thermoelectric power generation structure 10 will now be described in more detail.

For optimum resistance to the potentially hypersonic, erosive high temperature gas path in thermoelectric power generation structure 10, hot face liner 14 is preferably a ceramic material, more preferably a ceramic matrix composite (CMC) material. Hot face liner 14 may be formed from one or more of carbon fiber reinforced silicon carbide (C/SiC), carbon fiber reinforced carbon (C/C), silicon carbide fiber reinforced silicon carbide (SiC/SiC), silicon melt infiltrated SiC fiber reinforced SiC (MI SiC/SiC), or other suitable ceramic or ceramic matrix composite materials known in the art.

It is recognized that maximum thermoelectric output of the invention depends on the temperature difference between the hot and cold junctions of the thermoelectric elements in thermoelectric power generation structure 10. Establishing good thermal connections between the thermoelectric elements and the ceramic hot face liner to maximize the hot junction temperature of TE element 20 is a key design issue. Thermoelectric elements with flat mating surfaces are readily available but do not physically interface well with curved surfaces of cylindrical components such as ceramic matrix composite hot face gas path channels. In commonly owned Patent Application No. US 2011/0219775, methods to improve the surface finish of ceramic matrix composite materials by depositing a hardenable, machinable material on the surface of the ceramic matrix composite were disclosed and are incorporated herein in their entirety. In one embodiment, thermally conductive silicon was deposited as a hardenable machinable material. In the present invention, silicon may be deposited as thermally conductive shaped layer 16 on ceramic matrix composite hot face liner 14. Machining flats on thermally conductive shaped layer 16 then allows flat thermoelectric elements 20 to be easily attached to ceramic matrix composite liner 14 with a close fitting, thermally conductive interface. Although not limited to silicon alone for the present application, the material is well suited as a thermal interface between gas path 12 and thermoelectric elements 20 because of its 1410° C. melting point and excellent thermal conductivity of 84W/m·K, where W, m, and K designate watt, meter, and degree Kelvin, respectively.

Optional reaction barrier layer 18 between thermally conductive shaped layer 16 and thermoelectric elements 20 may be required to manage the thermal conductivity between the hot gas path and the thermoelectric elements. If increased thermal conductivity is desired, for instance, a layer of silicon carbide with a thermal conductivity of 40W/m·K may be deposited. If lower thermal conductivity is a goal, a layer of colloidal silica with a thermal conductivity of 2W/m·K may be deposited.

Thermoelectric element 20 may be any device known in the art that can withstand the operating environment of the present invention. Examples include, but are not limited to, lead telluride/tellurium-antimony-germanium-silver (PbTe/TAGS) device, silicon germanium (SiGe) device and others known in the art.

Metal cooling ducts 24 comprise a heat exchanger connected to outer surfaces 21 of TE elements 20 wherein fluid 26 carries heat away from the backside of TE elements 20 and increases the temperature gradient between the hot and cold TE junctions on element 20 thereby increasing the TE energy output.

Optional compliant layer 22 acts as an interface between metal cooling ducts 24 and TE elements 20. In operation, compliant layer 22 deforms and increases thermal and physical contact between outer surfaces 21 of TE elements 20 and metal cooling ducts 24. Compliant layer 22 needs to have high thermal conductivity and deformability to maximize thermal communication between TE elements 20 and metal cooling ducts 24. Compliant layer 22 may be oxygen free high conductivity copper (OFHC) in the dead soft annealed condition. “Dead soft annealed” is a term describing a fully annealed material with typically low hardness. Dead soft annealed OFHC copper may have a hardness less than 45 Rockwell F. The thermal conductivity of OFHC copper, as noted earlier, is 391W/m·K.

Canted metal springs 28 are one embodiment of the invention that applies a compressive clamping force on structure 10 to maximize thermal and physical contact across all mating interfaces in thermoelectric power generation structure 10. The constant clamping load over a large spring displacement makes canted springs a good candidate for this application. For optimal pressure control, the canted coil springs react against metal shell 30 or a metal strap. High temperature superalloy springs are well known in the art and available. Other clamping mechanisms known in the art are also possible, such as coil springs and compression springs.

Protective metal shell 30 surrounds the structure, restrains the canted springs and provides atmosphere control within thermoelectric power generation structure 10, if necessary.

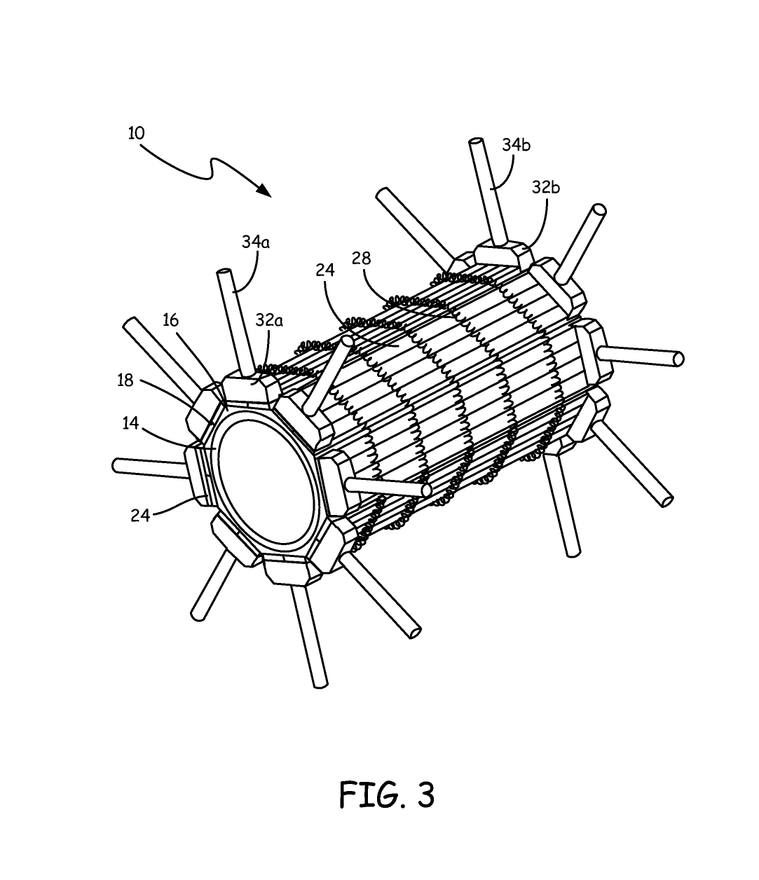

A perspective view of a test module of the enclosure without the exterior shell is shown in FIG. 3 with each separate component marked accordingly. Coolant inlet and outlet manifolds 32a and 32b and their respective tubes 34a and 34b that supply fluid coolant to metal cooling ducts 24 are also shown.

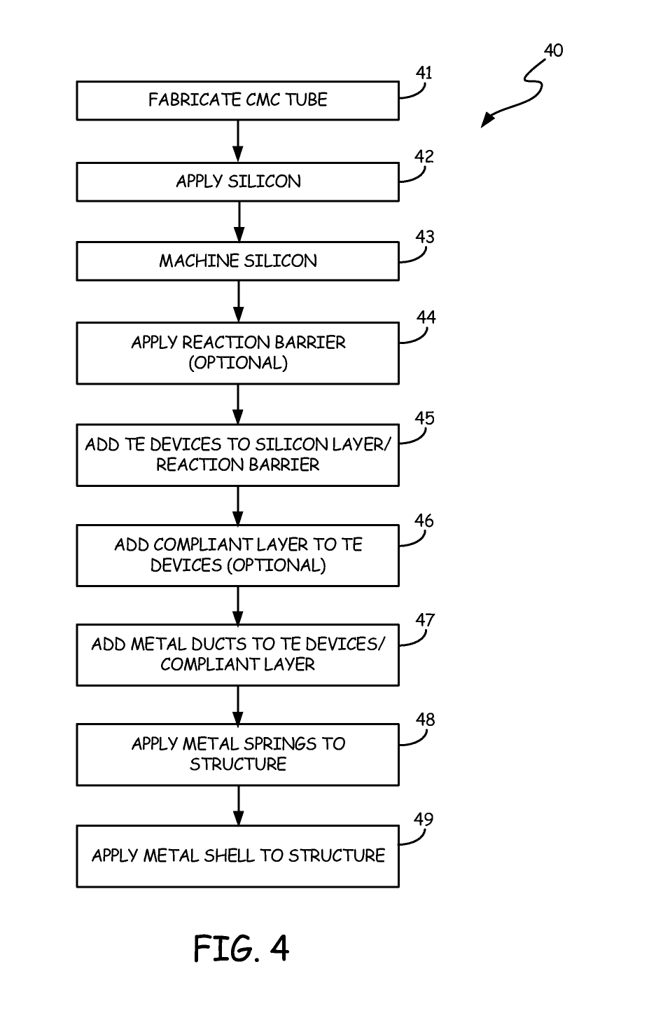

FIG. 4 is method 40 for forming thermoelectric power generation system 10 according to an embodiment of the present invention.

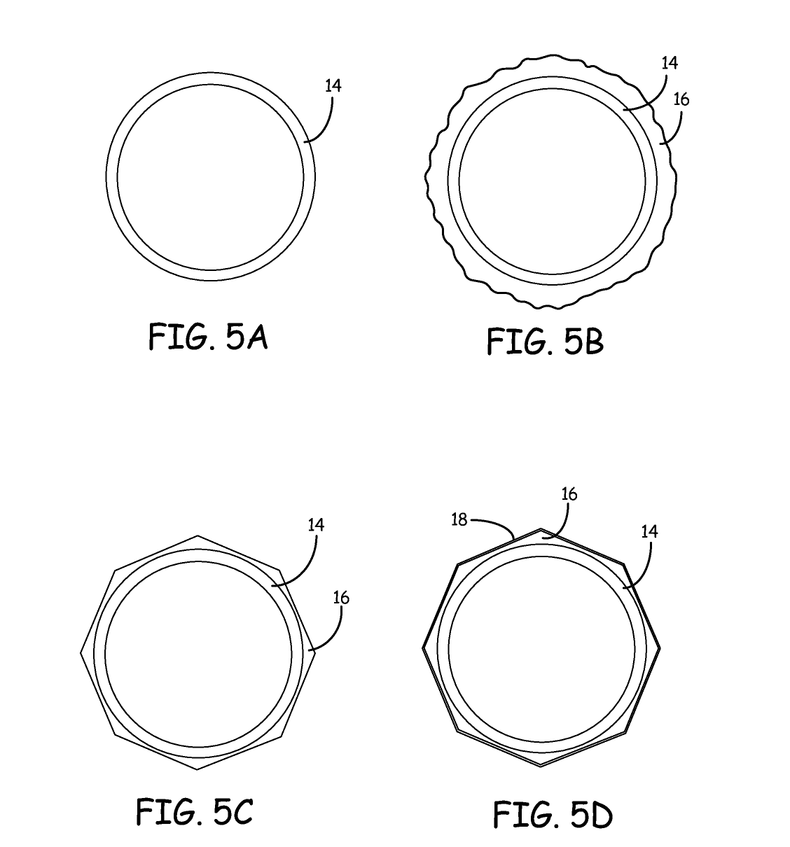

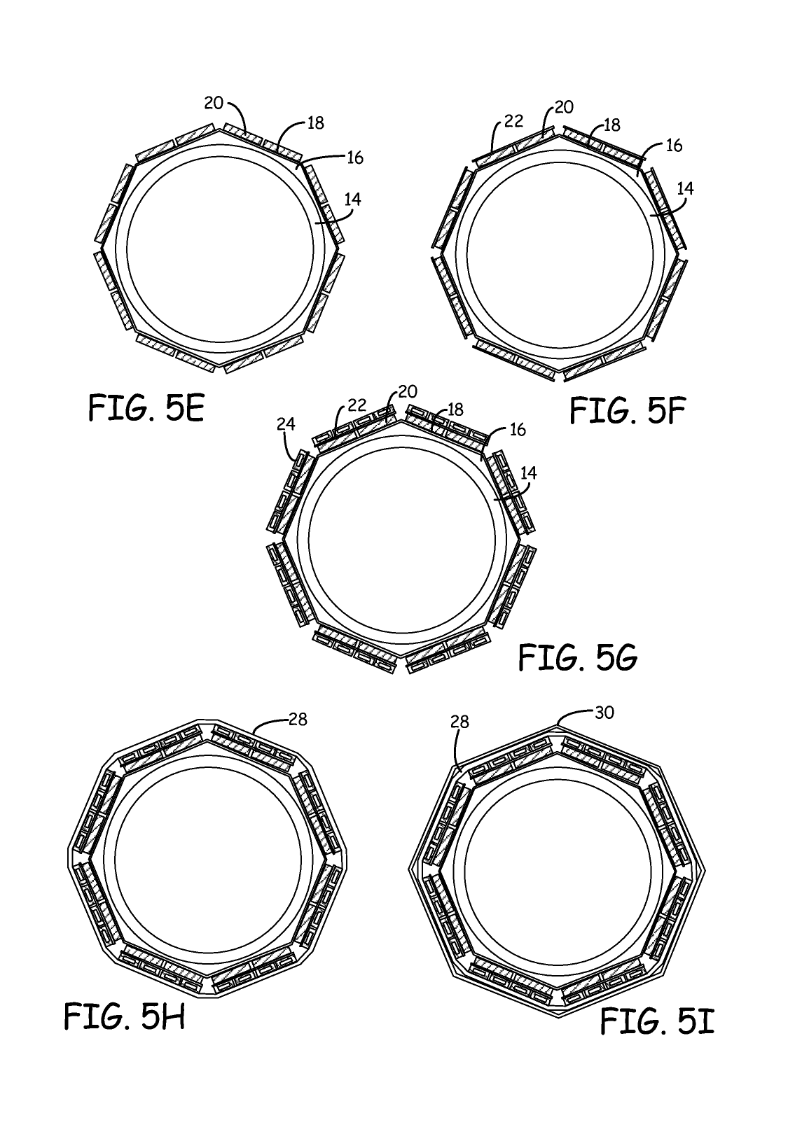

FIGS. 5A-5I illustrate an embodiment of method 40 for the assembly of thermoelectric power generation system 10 with each component numbered accordingly.

In first step 41, a ceramic matrix composite (CMC) tube to contain a hot gas path is fabricated to form liner 14 (FIG. 5A). The CMC tube containment structure may be fabricated by procedures such as chemical vapor infiltration (CVI), polymer impregnation and pyrolysis (PIP), and other procedures known in the art. While a tube structure is a feature of the gas path enclosure of the present embodiment, the invention is not limited to tubes and other enclosures such as flat and curved panels are possible.

In step 42, thermally conductive shaped layer 16 is formed (FIG. 5B). In an embodiment, thermally conductive shaped layer 16 is formed by depositing silicon on CMC liner 14. Silicon may be deposited by air plasma spray or other means known in the art. Silicon is well suited as a thermally conductive shaped layer because of its high thermal conductivity (84 W/m·K), high melting point (1410° C.), chemical stability and machinability. Silicon has also demonstrated excellent bonding and chemical compatibility with SiC based CMCs, such as C/SiC, SiC/SiC, C/C and MI SiC/SiC.

In step 43, flat surfaces are formed on thermally conductive shaped layer 16 (FIG. 5C). A preferred method of shaping is diamond grinding.

In step 44, optional reaction barrier layer 18 may then be applied to thermally conductive shaped layer 16 (FIG. 5D). The material for reaction barrier layer 18 depends on the thermal conductivity required of the layer. If a high thermal conductivity reaction barrier is desired, a thin vapor deposited silicon carbide layer may be a candidate. If a low thermal conductivity reaction barrier is desired, a colloidal silica layer may be a candidate.

In step 45, thermoelectric elements 20 are then mounted on thermally conductive shaped layer 16 or optional reaction barrier layer 18 such that inner surfaces 19 of TE elements 20 are in direct thermal and physical contact with shaped layer 16 or reaction barrier layer 18 (FIG. 5E).

In step 46, optional compliant layer 22 is added to thermoelectric elements 20 (FIG. 5F). This is to enhance thermal and physical contact between thermoelectric elements 20 and metal cooling ducts 24 to be added in the next step to maximize the thermal gradient across thermoelectric elements 20 by thermal conduction through outer surface 21. An optimum candidate material for compliant layer 22 is oxygen free high conductivity copper (OFHC) in the dead soft mechanical condition. OFHC copper has a thermal conductivity of 391W/m·K. In the dead soft condition, OFHC copper conforms well to the shape of the thermoelectric elements and to metal cooling ducts 24 to be added in the next step.

In step 47, metal cooling ducts 24 (or heat exchangers, HEX, as they are known in the art), are then added to thermoelectric elements 20 or optional complaint layer 22 (FIG. 5G). The HEX tubes 24 connect to inlet and outlet manifolds 32a and 32b and inlet and outlet coolant supply tubes 34a and 34b on both ends as shown in FIG. 3. The HEX tubes carry a coolant to maximize the thermal gradient in thermoelectric elements 20.

In step 48, metal springs 28 are added to metal cooling ducts (HEX tubes) 24 to clamp the overall assembly in compression against ceramic matrix composite hot face liner 14 (FIG. 5H). Canted metal coil springs 28 are ideal for this application because they have a relatively constant clamping force over a large displacement. They can be fabricated from a wide range of high temperature metals including Inconel and stainless steel.

In step 49, metal shell 30 is added to the structure to form an outer enclosure and to maintain canted coil springs 28 in a compressed form (FIG. 5I). Enclosure 30 may also be used to maintain a protective atmosphere around thermoelectric power generation system 10.

It should be noted that an additional protective ceramic coating may be applied to the inside of ceramic matrix composite liner 14 as added protection against oxidation, moisture, erosion, etc. in the hot gas stream. Coatings have been developed that are specific to different types of ceramic matrix composites and atmospheres. Candidate coatings are the subject of commonly owned Patent No. U.S. Pat. No. 7,951,459 which is incorporated herein in its entirety.

The present invention is a unique structure that combines the previously noted commonly owned U.S. 2011/0219779 patent application as well as commonly owned U.S. 2007/0018038 and U.S. 2010/0242437 patent applications incorporated herein in their entirety as well as other inventive concepts into a single structure.

Addition of a thermally conductive, machinable silicon layer on a fiber reinforced ceramic matrix composite (CMC) gas path liner enabled flat mating surfaces of thermoelectric elements to be mounted on flat surfaces machined on the liner to provide maximum thermal conductivity between the silicon layer and the thermoelectric elements. This maximizes the temperature of the thermoelectric hot junction and resulting thermoelectric power.

Silicon has excellent chemical compatibility with SiC, C, SiNC and other CMC components and forms strong bonds when coated on these materials. The material is readily machined to high tolerances and has a thermal conductivity of 84W/m.K and 1410° C. melting point.

Providing a machinable interface on fiber reinforced ceramic matrix composites (CMC) allows CMC components to be shaped by machining without rupturing fibers in the ceramic matrix.

Silicon acts as a heat spreader between the CMC hot face liner and thermoelectric devices. A more uniform temperature across the TE element contact area increases the power output of the element.

The structure is able to accommodate differential thermal expansion between components under both steady state and transient operating conditions thereby minimizing thermally induced stresses.

Clamping devices such as canted springs apply controllable loading at pressures that will not damage the TE elements.

Compliant layers between the TE elements and adjacent components and canted springs allow looser dimensional tolerances to be adapted in complicated structures such as thermoelectric power generation structure 10 of the present invention. Fasteners and hardware have been eliminated from prior art designs that have results in an areal density savings of about 4 Kg/m².

Atmosphere control is provided by locating thermoelectric elements between the CMC hot face liner and a continuous metal shell.

The following are non-exclusive descriptions of possible embodiments of the present invention.

An electric power generation system can include a cylindrical ceramic liner of a hot gas path enclosure; a thermally conductive conformal layer on the liner shaped to form a plurality of conformal mounting surfaces for thermoelectric elements mounted on the thermally conductive conformal layer with an inner surface of each element adjacent one of the conformal mounting surfaces; cooling channels connected to an outer surface of the thermoelectric elements; and a clamp that surrounds the ceramic liner, thermally conductive conformal layer, thermoelectric elements, and cooling channels for applying a compressive clamping force to maintain thermal and physical contact between the ceramic liner, thermally conductive conformal layer, thermoelectric elements, and cooling channels.

The system of the preceding paragraph can optionally include, additionally and/or alternatively any, one or more of the following features, configurations and/or additional components:

a ceramic matrix composite (CMC);

a ceramic matrix composite selected from the group consisting of carbon fiber reinforced silicon carbide (C/SiC), carbon fiber reinforced carbon (C/C), silicon carbide fiber reinforced silicon carbide (SiC/SiC), silicon melt infiltrated silicon carbide reinforced silicon carbide (MI SiC/SiC), and mixtures thereof;

a thermally conductive conformal layer comprising silicon;

thermoelectric elements comprising one or more of silicon germanium (SiGe), lead telluride/tellurium-antimony-germanium-silver (PbTe/TAGS), and mixtures thereof.

cooling channels comprising metal channels carrying a fluid coolant;

a clamp to maintain thermal and physical contact between the components comprising springs, such as canted metal coil springs surrounding the enclosure, thereby putting the components under compression;

a reaction barrier layer between the conformal layer and the thermoelectric elements;

a compliant layer between the thermoelectric elements and the cooling channels;

an outer protective metal shell.

A method can include fabricating a ceramic hot gas path liner; depositing a layer of thermally conducting material on the liner; forming flat conformal surfaces on the thermally conducting layer; adding thermoelectric elements to the flat conformal surfaces of the thermally conducting layer such that an inner surface of the thermoelectric elements is in direct thermal and physical contact with the flat conformal surfaces of the thermally conducting layer; adding metal cooling ducts to the outer surfaces of the thermoelectric elements such that the surfaces of the metal cooling ducts are in direct thermal and physical contact with the outer surfaces of the thermoelectric elements; and applying a compressive clamping force to the metal cooling ducts, thermoelectric elements, thermally conducting layer, and hot gas path liner to maintain thermal and physical contact between them that creates a thermal gradient in the thermoelectric elements and forms an electric power generation system.

The method of the preceding paragraph can optionally include, additionally and/or alternatively any, one or more of the following features, configurations, and/or additional components:

the ceramic hot gas path liner comprises a ceramic matrix composite (CMC);

the ceramic matrix composite is selected from the group consisting of carbon fiber reinforced silicon carbide (C/SiC), carbon fiber reinforced carbon (C/C), silicon carbide fiber reinforced silicon carbide (SiC/SiC), silicon melt infiltrated silicon carbide fiber reinforced silicon carbide (MI SiC/SiC), and mixtures thereof;

the thermally conducting material comprises silicon;

the thermoelectric elements comprise silicon germanium (SiGe), lead telluride/tellurium-antimony-germanium-silver (PbTe/TAGS), and mixtures thereof;

the cooling channels comprise metal channels carrying a fluid coolant;

the clamp to maintain thermal and physical contact between the components comprises springs, such as canted metal coil springs, surrounding the enclosure, thereby putting the components under compression;

a reaction barrier between the conformal layer and the thermoelectric elements;

a compliant layer between the thermoelectric elements and the cooling channels;

an outer protective metal shell.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. An electric power generation system comprising:
a ceramic liner of a hot gas path enclosure;
a thermally conductive conformal layer on the liner shaped to provide a plurality of conformal mounting surfaces;
thermoelectric elements mounted on the thermally conductive conformal layer with an inner surface of each thermoelectric element adjacent one of the conformal mounting surfaces of the thermally conductive conformal layer;
cooling channels connected to an outer surface of the thermoelectric elements; and
a clamp that surrounds the ceramic liner, thermally conductive conformal layer, thermoelectric elements, and cooling channels for applying a compressive clamping force to maintain thermal and physical contact between the ceramic liner, thermally conductive conformal layer, thermoelectric elements and cooling channels.

2. The system of claim 1, wherein the ceramic liner comprises a ceramic matrix composite (CMC).

3. The system of claim 2, wherein the ceramic matrix composite is selected from the group consisting of carbon fiber reinforced silicon carbide (C/SiC), carbon fiber reinforced carbon(C/C), silicon carbide fiber reinforced silicon carbide (SiC/SiC), silicon melt infiltrated silicon carbide reinforced silicon carbide (MI SiC/SiC) and mixtures thereof.

4. The system of claim 1, wherein the thermally conductive conformal layer comprises silicon.

5. The system of claim 1, wherein the cooling channels comprise metal channels for carrying a fluid coolant.

6. The system of claim 1, wherein the clamp to maintain thermal and physical contact between the components comprises springs surrounding the enclosure thereby putting the components under compression.

7. The system of claim 6, wherein the springs are canted coil springs.

8. The system of claim 1 further comprising a reaction barrier layer between the conformal layer and the thermoelectric elements.

9. The system of claim 1 further comprising a compliant layer between the thermoelectric elements and the cooling channels.

10. The system of claim 1 further comprising an outer protective metal shell.

11. A method comprising:
fabricating a ceramic hot gas path liner;
depositing a layer of thermally conducting material on the liner;
forming flat conformal surfaces on the thermally conducting layer;
adding thermoelectric elements to the flat conformal surfaces of the thermally conducting layer such that an inner surface of the thermoelectric elements is in direct thermal and physical contact with the flat conformal surfaces of the thermally conducting layer;
adding metal cooling ducts to the outer surface of the thermoelectric elements such that the surfaces of the metal cooling ducts are in direct thermal and physical contact with the outer surfaces of the thermoelectric elements; and
applying a compressive clamping force to the metal cooling ducts, thermoelectric elements, thermally conducting layer, and hot gas path liner to maintain thermal and physical contact between them that creates a thermal gradient in the thermoelectric elements and forms an electric power generation system.

12. The method of claim 11, wherein the ceramic hot gas path liner comprises a ceramic matrix composite (CMC).

13. The method of claim 12, wherein the ceramic matrix composite comprises at least one of carbon fiber reinforced silicon carbide (C/SiC), carbon fiber reinforced carbon (C/C), silicon carbide fiber reinforced silicon carbide (SiC/SiC), silicon melt infiltrated silicon carbide fiber reinforced silicon carbide (MI SiC/SiC), and mixtures thereof.

14. The method of claim 11, wherein the thermally conducting material comprises silicon.

15. The method of claim 11, wherein the cooling channels comprise metal channels carrying a fluid coolant.

16. The method of claim 11, wherein the clamp to maintain thermal and physical contact between the components comprises springs surrounding the enclosure, thereby putting the components under compression.

17. The method of claim 16, wherein the springs are canted coil springs.

18. The method of claim 11, further comprising forming a reaction barrier layer between the conformal layer and the thermoelectric elements.

19. The method of claim 11, further comprising forming a compliant layer between the thermoelectric elements and the cooling channels.

20. The method of claim 11, further comprising positioning an outer protective metal shell around the electric power generation system.
